(19) United States
(12) Patent Application Publication
(10) Pub. No.: US 2026/0343879 A1
(43) Pub. Date: Oct. 29, 2026

(54) EMBEDDED FLASH MEMORY OF 110 NM OR LESS AND MANUFACTURING METHOD THEREOF

(71) Applicant: Chengdu Analog Circuit Technology Inc., Chengdu (CN)

(72) Inventors: Jingwei CHEN, Chengdu (CN); Feilong CHEN, Chengdu (CN); Zhen YANG, Chengdu (CN); Yulong WANG, Chengdu (CN); Jianjun XIANG, Chengdu (CN)

(73) Assignee: Chengdu Analog Circuit Technology Inc., Chengdu (CN)

(21) Appl. No.: 19/657,070

(22) Filed: Apr. 24, 2026

(30) Foreign Application Priority Data
Apr. 25, 2025 (CN) 202510531503.X

(51) Int. Cl. H10B 41/42; H10B 41/35; H10B 41/41

(52) U.S. Cl. CPC H10B 41/42; H10B 41/35; H10B 41/41

(57) ABSTRACT

An embedded flash memory of 110 nm or less and a manufacturing method thereof are provided. The embedded flash memory comprises a substrate, and a memory cell array region and a peripheral logic region on the substrate. The memory cell array region comprises at least one memory cell comprising: a common source in the substrate; a common line over the common source and connected thereto; a pair of stacked gates located respectively on two sides of the common line, each stacked gate comprising a floating gate and a control gate vertically over the floating gate; a pair of select gates located respectively on the side of the stacked gate opposite to the common source line. The peripheral logic region comprises at least one logic transistor comprising a logic gate. The control gate in the memory cell has the same height as the logic gate in the logic transistor.

### CROSS-REFERENCE TO THE RELATED APPLICATIONS

This application is based upon and claims priority to Chinese Patent Application No. 202510531503.X, filed on Apr. 25, 2025, the entire contents of which are incorporated herein by reference.

### TECHNICAL FIELD

This invention pertains generally to embedded flash memories of 110 nm or less and manufacturing methods thereof, particularly to embedded flash memories of 90 nm or less and manufacturing methods thereof.

### BACKGROUND

The embedded flash memory, referred to as eFlash, is used widely in electronic products such as Micro Control Units (MCUs), Digital Signal Processors (DSPs), Application Specific Integrated Circuits (ASICs), Programmable Logic Devices (PLDs), and the like. As compared with the traditional EEPROM scheme, eFlash has advantages of high read-write speed, small area, low power-dissipation and the like, and plays an increasingly important role in current application scenarios such as the Internet of Things (IoT) and automotive electronics.

In solutions of embedded flash memory, there are mainly a traditional structure based on a floating gate and a charge-trapping structure. In the charge-trapping structure, electrons are "trapped" in an insulating storage medium via a charge "trapping" mechanism. The scheme is used mainly in Silicon-Oxide-Nitride-Oxide-Silicon (SONOS). For example, layers of silicon oxide, silicon nitride, and silicon oxide are sequentially deposited on a silicon substrate. It could be fabricated in a simply way, but the reliability is not good, due to inherent properties of nitride. So it can be used only in consumer products. For advanced application, it still requires for an embedded flash memory with a floating-gate structure.

Among the embedded flash memories with a floating-gate structure, ESF3 structure of Silicon Storage Technology Inc. (SST) in the United States is mostly used at present. In the structure, there are three layers of gates, comprising an Erase Gate (EG), a Control Gate (CG) and a Floating Gate (FG). The programming operation is carried out by side injection from the source, the erase is carried out by a gate-to-gate mode. It can achieve over 300,000 times of repetitive read and write, has good reliability and application scenarios. However, the ESF3 structure is a little bit difficult to be fabricated, in which an erase gate needs to wrap the floating gate for sufficient erase efficiency and low erase voltage. Further, three different gates need to be formed in a process, which is a little bit difficult to control the process with uniformity, and mass process window is small.

Another commonly used embedded flash memory has a dual-transistor (2T) structure of NXP Semiconductors N.V. (NXP) in the Netherlands. The memory cell of the memory comprises a pair of select gates (SG) and a pair of stacked gates in bilaterally mirror-symmetrical. In the stacked gate, a Control Gate (CG) is stacked over a Floating Gate (FG). As compared with the ESF3 of SST, the structure and fabrication are simpler. Programming operation is carried out by Fowler-Nordheim tunneling, which requires a high voltage and results in a large area of pump circuit of peripheral logic region, and the high voltage also affects the reliability of the flash memory device.

Memory elements in an embedded flash memory need to be compatible with a logic process for fabricating the logic elements, and generally the height (or thickness) of memory elements in the embedded flash memory need to align with those of logic elements. For example, in an embedded flash memory with a 2T-structure fabricated in a process node of 110 nm or above currently in China, the peripheral logic element has a logic gate height of about 2000 Å, the memory element has a CG height of about 1200 Å, a FG height of about 800 Å, and a SG height of about 2000 Å. With the increasing requirement for smaller size of the memory in the industry, gate heights of both logic element and memory element need to be reduced accordingly. In a process of 110 nm or less, for example 90 nm or less, gate height of peripheral standard logic transistor in an embedded flash memory is required to be reduced from previous 2000 Å to about 1000 Å. If fabricated by a current process, such as 110 nm or above, to ensure a sufficient coupling rate of the memory element, a FG height has to be greater than 750 Å, thereby results in a CG height of less than 300 Å. In this case, in a subsequent step of dopant ion implantation (IMP) in the process, the implanted ions could easily penetrate the CG and implanted into the below ONO layer, affecting reliability of the flash. Therefore, there is a demand in the industry for a smaller-size embedded flash memory with good performance, particularly a new manufacturing method therefor.

### SUMMARY

An object of the invention is to provide an embedded flash memory of 110 nm or less, which comprises a substrate, and a memory cell array region and a peripheral logic region on the substrate. The memory cell array region comprises at least one memory cell, which comprises: a common source in the substrate, a common line over the common source and connected thereto, a pair of stacked gates located respectively on two sides of the common line and each stacked gate comprising a floating gate and a control gate vertically over the floating gate; a pair of select gates located respectively on the side of the stacked gate opposite to the common source line. The peripheral logic region comprises at least one logic transistor comprising a logic gate. The control gate in the memory cell has the same height as the logic gate in the logic transistor.

Another object of the invention is to provide a method for manufacturing the embedded flash memory of 110 nm or less, which comprises the steps of forming the control gate in the memory cell and the logic gate in the logic transistor by depositing simultaneously a layer of gate material on the predefined areas of the memory array region and the peripheral logic region in the same deposition step, and then separately etching the layer of gate materials in the memory array region and the peripheral logic region by using different photomasks.

In present invention, the control gate of the memory cell is formed by the same deposition step as the logic gate of the logic transistor, and thereby has the same height as the logic gate of the logic transistor. Thus, the defect caused by a too thin control gate of memory cell in the smaller-size embedded flash memory is avoided. The reliability of the memory can be guaranteed, and the stable performance of the embedded flash memory is obtained. In addition, the fabrication of the embedded flash memory of present invention is simple and convenient with a low cost.

### BRIEF DESCRIPTION OF THE DRAWINGS

In the drawings, an identical reference numeral refers to an identical or similar element.

FIG. 1 is a partial top view of an embodiment of an embedded flash memory of the invention.

FIG. 2 is a cross-section of the substrate in the memory of FIG. 1 taken along the section line B-B before starting to form memory cell and logic transistor.

FIG. 3 is a schematic diagram of the substrate of FIG. 2 in the step of forming a N-well therein for the memory array.

FIG. 4 is a schematic diagram of the substrate of FIG. 3 in the step of sequentially depositing a layer of gate oxide material and a layer of lower gate material thereon.

FIG. 5A is a schematic diagram of the structure of FIG. 4 before etching in deposition layer of lower gate material in the predefined area of each row of memory cells in memory array region to form the gap (PC) between two corresponding floating gates of adjacent memory cells in the row.

FIGS. 5B-5C are top views of a row of memory cells in memory array region of the flash of FIG. 1 respectively before and after etching to form the gap (PC) between two corresponding floating gates of adjacent memory cells in the row.

FIG. 5D is a schematic diagram of the structure of FIG. 4 after etching in deposition layer of lower gate material in the predefined area of each row of memory cells in memory array region to form the gap (PC) between two corresponding floating gates of adjacent memory cells in the row, and etching to remove the layer of lower gate material in the predefined area of logic region.

FIG. 6 is a schematic diagram of the structure of FIG. 5D in the step of depositing a layer of dielectric material on the layer of lower gate material in the memory array region and on the layer of gate oxide in the logic region.

FIG. 7A is a schematic diagram of the structure of FIG. 6 in the step of etching to remove the deposited layer of dielectric material in the logic region.

FIG. 7B is a top view of a row of memory cells in memory array region of the flash of FIG. 1 in the step of etching to form the via hole in the dielectric layer.

FIG. 8A is a schematic diagram of the structure of FIG. 7A in the step of forming the P-well and N-well for logic elements in a low-voltage (LV) logic region and a high-voltage (HV) logic region in the substrate respectively.

FIG. 8B is a schematic diagram of the structure of FIG. 8A in the step of etching to remove the gate oxide layer in the low-voltage and high-voltage logic regions, previously formed along with the fabrication of memory cells in memory array.

FIG. 9 is a schematic diagram of the structure of FIG. 8B in the step of regrowing a layer of low-voltage gate oxide and a layer of high-voltage gate oxide respectively in the low-voltage region and high-voltage logic region.

FIG. 10 is a schematic diagram of the structure of FIG. 9 in the step of depositing a layer of upper gate material on the dielectric layer in the memory array region and on the gate oxide layer in the logic region.

FIGS. 11A-11B are schematic diagrams of the structure of a memory cell in the flash of FIG. 1 taken along the section line C-C before and after etching to form the gate respectively.

FIGS. 11C-11D are schematic diagrams of the structure of a low-voltage logic element in the flash of FIG. 1 taken along the section line D-D before and after etching to form the gate of the low-voltage logic element respectively.

FIGS. 11E-11F are schematic diagrams of the structure of a high-voltage logic element in the flash of FIG. 1 taken along the section line E-E before and after etching to form the gate of the high-voltage logic element respectively.

FIGS. 12A-12B are schematic diagrams of the structure of a memory cell in the flash of FIG. 1 taken along the section line C-C in the steps of sequentially forming spacers on outer side of the gates, implanting dopant ion into source location and drain location, and removing the gate oxide layer away from upper surface of source and drain, respectively.

FIG. 13 is a circuit diagram of a 2×2 memory array in the flash of FIG. 1.

FIG. 14 shows bias signals connected to the two memory cells in the first row of the memory array of FIG. 13 during different operations.

### DETAILED DESCRIPTION OF THE EMBODIMENTS

Relevant term definitions in the present invention are described as follows.

The “height” mentioned herein refers to a dimension of an element in an upward direction perpendicular to the surface of the substrate of the memory, also referred to as the “thickness” of the element.

The “upward” , “up”, or “down” mentioned herein refer to an up-and-down relationship in a direction perpendicular to the surface of the substrate of the memory.

The expression “the select gate has substantially the same height as the stacked gate” means that no dielectric layer is sandwiched between the upper gate part and the lower gate part of the select gate, so that the height of the select gate is slightly lower than that of the stacked gate; and the height difference is equal to the height of the dielectric layer in the stacked gate.

The expression "corresponding gates of memory cells in each row" mentioned herein, refer to the gates at the same position in all memory cells in the row, and the gates can be directly connected into a straight line in the row along the row direction. The gates can be select gates, control gates, the floating gates, upper gate parts of select gates, or lower gate parts of select gates. So applies to the expression "corresponding gates of memory cells in each column".

The embedded flash memory of present invention is a small-sized embedded flash memory, preferably an embedded flash memory of 110 nm or less, and more preferably an embedded flash memory of 90 nm or less.

The embedded flash memory of present invention comprises a memory array region composed of memory cells and a logic region composed of peripheral logic elements. The logic elements are preferably standard logic elements, comprising standard logic transistors.

The peripheral logic region may comprise a low-voltage region and/or a high-voltage region. The low-voltage region may comprise a plurality of low-voltage logic elements, preferably low-voltage standard logic elements (or standard logic transistors). The types of the low-voltage logic transistors may be different from each other according to specific use thereof, and the types of wells where the low-voltage logic transistors are located are also different therefore. Similarly, the high-voltage region may comprise a plurality of high-voltage logic elements, preferably high-voltage standard logic elements (or standard logic transistors). The types of the high-voltage logic transistors may be different from each other according to predefined use thereof, and the types of wells where the high-voltage logic transistors are located are also different therefore.

All logic elements (or logic transistors) in the logic region have a logic gate with the same height, and the gates are formed by deposing a layer of gate material in the same deposition step and followed by etching.

In the memory array region, all memory cells are identical, and have a bilaterally mirror-symmetrical structure.

The memory cell comprises:
a common source in the substrate;
a common line (COM) over the common source and connected to the common source below;
a pair of stacked gates on the substrate, respectively located on both sides of the common line in bilateral mirror symmetry, wherein each stacked gate comprises a floating gate (FG) and a control gate (CG) vertically over the FG, and the FG and CG are vertically aligned with each other;

two select gates (SG) on the substrate, respectively located on the side of the stacked gate opposite to the common line, in bilateral mirror symmetry with respect to the common line; two drains are located in the substrate respectively on the side of the select gate opposite to the stacked gate.

The control gate of the memory cell of the present invention has the same height as the logic gate of the logic transistor. Thus, the defect caused by too-thin control gate of the memory cell in the small-size flash memory is avoided, the reliability of the memory cell can be guaranteed, and the memory cell has good and stable performance. The control gate in the memory cell and the logic gate in the logic transistor are formed in such a manner that a layer of gate material is simultaneously deposited in predefined area of the memory array region and the peripheral logic region in the same deposition step, and then the layer of gate material deposited on the memory array region and the peripheral logic region are etched separately by using different photomasks.

In the present invention, preferably, the select gate of the memory cell has the same or substantially the same height as the stacked gate. Thus, the memory cell has a simple structure, convenient to fabricate, and has reliable and stable performance. More preferably, the select gate and the stacked gate are completely identical in height, and most preferably, the select gate and the stacked gate are completely identical in structure and height. Thus, the control on uniform and precise etching in the manufacturing process can be easily realized, and electric leakage caused by slight over-etching is avoided, so that the reliability is kept consistent. The select gate comprises an upper gate part and a lower gate part, which are also referred to as the upper part and lower prat of the select gate respectively in present invention.

In a specific preferred embodiment, in the stacked gate, a dielectric layer is present between the control gate and the floating gate; the upper part and the lower part of the select gate have the same height as the control gate and the floating gate respectively, a dielectric layer is also present between the upper part and lower part of the select gate and has the same height as the dielectric layer in the stacked gate; and the lower part of the select gate is electrically connected to above the dielectric layer. In this case, the select gate and the stacked gate are formed together through the same fabrication steps.

In the case that the select gate of the memory cell has substantially the same height as the stacked gate, a dielectric layer is sandwiched between the control gate and the floating gate in the stacked gate, but no dielectric layer is present between the upper part and the lower part of the select gate. The upper part and lower part of the select gate are formed respectively through different deposition steps, but the two parts of the select gate are directly connected and merged together. In this case, the select gate and the stacked gate are formed together through substantially the same fabrication steps, with the difference that the fabrication of the select gate lacks of a step of forming the dielectric layer, as required in the fabrication of the stacked gate.

The memory cell array of the present invention is comprised of rows and columns, and preferably, all memory cells in the array are orientated identically.

In the case that the direction of a straight line connecting the same points of two select gates in a memory cell is column direction in memory array, preferably: the corresponding upper parts of the select gates or the corresponding control gates of the memory cells in each row are connected along the row to form a strip; whereas the corresponding floating gates of the memory cells in each row are not connected and are interrupted at gaps between two adjacent memory cells.

If no dielectric layer is present in the select gate, more preferably: the corresponding upper parts of the select gates of the memory cells in each row are connected along the row to form a strip, whereas the corresponding lower parts of the select gates of the memory cells in each row are not connected and interrupted at gaps between two adjacent memory cells like the floating gates. However, in each memory cell, the lower part and the upper part of each select gate contact with each or merge together.

If a dielectric layer is present in the select gate, more preferably: the corresponding upper parts or the corresponding lower parts of the select gates of the memory cells in each row are connected along the row to form a strip, and the lower strip of the select gate can be electrically connected to above the dielectric layer. More preferably: in each row, at least one via hole is formed in the dielectric layer between the vertically aligned upper strip and lower strip of the select gates. A bottom side of the via hole contacts and is electrically connected to upper surface of the lower strip of the select gate, and a top side of the via hole is exposed out on upper surface of the dielectric layer, so that the lower strip of the select gate can be electrically connected to above the dielectric layer, e.g. to the upper strip of the select gates. Still more preferably: in each row, a via hole is formed in the dielectric layer between the vertically aligned upper strip and lower strip of the select gates at an interval of from 8 to 64 memory cells, more preferably from 16 to 32 memory cells, along the row.

In the case that the direction of a straight line connecting the same points of two select gates in a memory cell is row direction in memory array, preferably: the corresponding upper parts of the select gates or the corresponding control gates of the memory cells in each column are connected along the column to form a strip; whereas the corresponding floating gates of the memory cells in each column are not connected and are interrupted at gaps between two adjacent memory cells.

If no dielectric layer is present in the select gate, more preferably: the corresponding upper parts of the select gates of the memory cells in each column are connected along the column to form a strip, whereas the corresponding lower parts of the select gates of the memory cells in each column are not connected and are interrupted at gaps between adjacent memory cells, like the floating gates. However, in each memory cell, the lower part and the upper part in each select gate contact with each other or merge together.

If a dielectric layer is present in the select gate, more preferably: the corresponding upper parts or the corresponding lower parts of the select gates of the memory cells in each column are connected along the column to form a strip; and the lower strip of the select gate can be electrically connected to above the dielectric layer. More preferably: in each column, at least one via hole is formed in the dielectric layer between the vertically aligned upper strip and lower strip of the select gates, a bottom side of the via hole contacts and is electrically connected to upper surface of the lower strip of the select gate, and a top side of the via hole is exposed out on top surface of the dielectric layer, so that the lower strip of the select gates can be electrically connected to above the dielectric layer, e.g. to the upper strip of the select gates. Still more preferably: in each column, a via hole is formed in the dielectric layer between the vertically aligned upper strip and lower strip of the select gates at an interval of from 8 to 64 memory cells, more preferably from 16 to 32 memory cells, along the column.

In the memory array of the present invention, in the case that the via hole is present in the dielectric layer between the upper strip and lower strip of select gates, preferably, a via hole is also formed in the upper strip of select gates at a position vertically over each via hole below in the dielectric layer, which is electrically insulated from the surrounding upper strip of select gates and internally electrically connected to the below via hole in the dielectric layer, with a bottom side extended through to the below via hole in the dielectric layer, and a top side exposed out on an upper surface of the upper strip of select gates. In this way, the via hole in the dielectric layer can be extended out to the upper surface of the upper strip of select gates.

In the memory array of the present invention, the common source of the memory cell is coupled to a common line (COM), the control gate is coupled to a control line (CG'), and the drain of the select gate is coupled to a bit Line (BL). In the case that no dielectric layer is present in the select gate, the upper part and the lower part of the select gate merge together and is coupled to a word Line (WL). In the case that a dielectric layer is sandwiched in the select gate, and the via hole absent in the upper strip of the select gates but present in the dielectric layer, the lower strip of the select gates is electrically connected to the upper strip of the select gates through the via hole in the dielectric layer and is connected to the Word Line (WL). In the case that the via hole present in both the upper strip of the select gates and the dielectric layer, and the via holes in the upper strip of SG and the dielectric layer are vertically extended through and electrically connected inside, preferably, the lower strip of the select gates is electrically connected to the word Line (WL) through the via holes in the upper strip of SG and the dielectric layer, whereas the upper strip of the select gates is not connected electrically to the word Line (WL). In this case, more preferably, a layer of electrical isolation wall is present on inner surface of the via holes in the upper strip of the select gates and in the dielectric layer, enclosing a metal wire standing upright and inside at the center of the vias. The metal wire is electrically insulated from the upper strip of the select gate by the isolation wall on the inner surface of the via holes.

In the memory array of the present invention, in the case that the direction of a straight line connecting the same points of two select gates in a memory cell is column direction, the bit lines (BL) of the memory cells in each column are connected; and the word lines (WL), common lines (COM), and control lines (CG') of the memory cells in each row are respectively connected.

In the case that the direction of a straight line connecting the same points of two select gates in a memory cell is row direction, the bit lines (BL) of the memory cells in each row are connected; and the word lines (WL), common lines (COM), and control lines (CG') of the memory cells in each column are respectively connected.

In the embedded flash memory of the present invention, the programming path is from channel region near common source to the floating gate, and the erase path is from the floating gate to channel region in the below substrate, which is simple and regular in the art, and no need to form a new path by additional components, such as an erase gate or a side protrusion of floating gate. Therefore, the memory cells of the present invention are simple in structure, and operations of programming and erasing are easy to perform.

In the memory cell array of the present invention, all memory cells can be erased together and programmed in a bit-selectable way.

The present invention also relates to a method of manufacturing or fabricating the embedded flash memory as mentioned above, which sequentially comprises the following steps.

A. Providing a substrate and forming a well of the memory cells:

A substrate is provided, on the surface of which, active areas and isolation areas are present alternately and adjacently. In the active areas, the memory cells and logic transistors are later formed. A well for the memory cells is formed in the substrate, below the predefined area of the memory array region, and all memory cells in the memory array share the well.

B. Depositing layers of gate oxide and lower gate material, and followed by etching:

On the substrate, a layer of gate oxide (also referred to as the gate oxide layer) is deposited first, and then a layer of lower gate material is deposited on the gate oxide layer. It is the first layer of the gate material deposited, also referred to as the layer of lower gate or the lower gate layer. The growth height of the gate oxide layer is preferably 80-95 Å. The growth height of the lower gate layer is preferably 750-1000 Å, and more preferably 800-900 Å. A too low height of the lower gate layer would affect performance of the memory device, for example, the coupling efficiency of the memory cell is reduced, and a too high height is not available in a fabrication process of flash memory.

Then, by using a photomask (also referred to as a photolithography mask), in the predefined area of memory array region, the deposited lower gate layer is etched and removed at predefined locations of gaps between two adjacent memory cells, specifically at predefined locations of gaps between two corresponding floating gates of adjacent memory cells, to form gaps between two corresponding floating gates of adjacent cells, and in the predefined area of peripheral logic region, the deposited lower gate layer is also etched and removed.

In the case that no dielectric layer is deposed between upper part and lower part in the select gates of the memory cells, preferably, the deposited lower gate layer is also etched and removed specifically at predefined locations of gaps between two corresponding lower parts of the select gates of adjacent memory cells, to form gaps between two corresponding lower parts of the select gates of adjacent memory cells. In the case that a dielectric layer is deposed in the select gates of the memory cells, no etching is carried out at locations between two corresponding lower parts of the select gates of adjacent memory cells.

In the case that the direction of a straight line connecting the same points of two select gates in a memory cell is column direction in the memory array, etching the deposited lower gate layer between two adjacent memory cells in the array means that: in predefined area of each row of memory cells, etching at predetermined locations of gaps between two corresponding floating gates of adjacent memory cells along the row; and if no dielectric layer is present in the select gate of the memory cell, the etching is preferably also performed at predetermined locations between two corresponding lower parts of the select gates of adjacent memory cells at the same time.

Alternatively, in the case that the direction of a straight line connecting the same points of two select gates in a memory cell is row direction in the memory array, etching the deposited lower gate layer between two adjacent memory cells in the array means that: in predefined area of each column of memory cells, etching at predetermined locations of gaps between two corresponding floating gates of adjacent memory cells along the column; and if no dielectric layer is present in the select gate of the memory cell, the etching is preferably also performed at predetermined locations between two corresponding lower parts of the select gates of adjacent memory cells at the same time.

C. Depositing a layer of dielectric material and followed by etching:

A layer of dielectric oxide material (referred to as a dielectric layer for short) is simultaneously deposited on the lower gate layer in entire memory array region, and on the gate oxide layer in the peripheral logic region. In the case that no dielectric layer is arranged between the upper part and lower part of the select gate of the memory cell, no dielectric oxide material is deposited on predetermined areas of the select gates.

Then, by using a photomask, the dielectric layer deposited in the logic region is etched and removed. If a dielectric layer is arranged between the upper part and lower part of the select gate of the memory cell, at the same time, via holes are formed by etching in the deposited dielectric layer over the predefined area of lower parts of the select gates in the memory array region.

The formation of via holes in the dielectric layer deposited in the memory array region comprises the following steps.

In the case that the direction of a straight line connecting same points of two select gates in a memory cell is column direction in the memory array, in predefined area of each row of memory cells, in a part of the dielectric material layer directly over predefined area of lower parts of select gates, at least one via hole is formed by etching, with a bottom side contacting an upper surface of the lower gate layer, and a top side exposing out on an upper surface of the dielectric layer. Preferably, a via hole is formed by etching at an interval of from 8 to 64 memory cells along the row, more preferably from 16 to 32 memory cells along the row.

In the case that the direction of a straight line connecting same points of two select gates in a memory cell is row direction in the memory array, in predefined area of each column of memory cells, in a part of the dielectric material layer directly over predefined area of lower parts of select gates, at least one via hole is formed by etching, with a bottom side contacting an upper surface of the lower gate layer, and a top side exposing out on an upper surface of the dielectric layer. Preferably, a via hole is formed by etching at an interval of from 8 to 64 memory cells along the column, more preferably from 16 to 32 memory cells along the column.

Fewer via holes help to reduce area of the memory array, while too fewer via holes cause voltage drop due to a long flow path along WL.

D. Forming wells for logic elements in logic region and a layer of logic gate oxide:

In the substrate below the predetermined area of peripheral logic region, wells of logic elements are formed. The formation of the wells of logic elements is delayed till this step, is to avoid undergoing above fabrication steps of memory cells and being affected thereby, so that performance of the wells of the logic elements keeps stable as required, for example, the dopant ion distribution in the wells keeps unchanged.

The logic region comprises a low-voltage and/or a high-voltage logic region. The low-voltage logic region may comprise a plurality of low-voltage logic elements (or logic transistors), preferably standard logic elements (standard logic transistors). The low-voltage logic transistors may be different from each other in type based on respective uses thereof, and different type wells are needed in the low-voltage region therefore. Therefore, it is required to form respective wells for different type logic elements to be used. The high-voltage logic region is similar to the low-voltage logic region.

Then, the gate oxide layer remained in the logic region is removed away by etching, which is formed along with fabrication of memory cells in memory array. Further, a new layer of logic gate oxide specifically for the logic gate is regrown in the logic region. There is a certain gap between the regrown gate oxide layer in the logic region and the previously formed gate oxide layer in the memory array region, so as to ensure insulation between the logic region and the memory array region. The gate oxide layer in the low-voltage logic region is thin, and the gate oxide layer in the high-voltage logic region is thick, depended on applicable voltage thereto in the predetermined use thereof.

E. Depositing a layer of upper gate material and forming respective gates by etching:

A layer of upper gate material, also referred to as the upper gate material layer or upper gate layer, is simultaneously deposited on the dielectric layer in entire array region and on the regrown logic gate oxide layer in the logic region.

Then, in the memory array region, a photomask is used to shield predetermined locations of select gates and control gates, and outside these locations, etching is performed down and stopped at upper surface of the gate oxide layer, so as to remove away the upper gate layer, lower gate layer, and the intermediate dielectric layer. Thereby, strips of upper parts of select gates, strips of control gates, strips of lower parts of select gates (if a dielectric layer present in the select gate), lower parts of select gates (if no dielectric layer present in the select gate), and the floating gates in memory array region, are simultaneously formed.

In particular, in the case that the direction of a straight line connecting same points of two select gates in a memory cell is column direction in the memory array, in predefined area of each row of memory cells, along the row, etching is carried out to form two strips of upper parts of select gates, two strips of control gates, two strips of lower parts of select gates (if a dielectric layer present in the select gate), lower parts of select gates (if no dielectric layer present in the select gate), and the floating gates in the row simultaneously. In the case that the direction of a straight line connecting same points of two select gates in a memory cell is row direction in the memory array, in predefined area of each column of memory cells, along the column, etching is carried out to form two strips of upper parts of select gates, two strips of control gates, two strips of lower parts of select gates (if a dielectric layer present in the select gate), lower parts of select gates (if no dielectric layer present in the select gate), and the floating gates in the column simultaneously.

Then, in the logic region, a photomask is used to shield predetermined locations of logic gates, and outside these locations, the upper gate material layer is etched and removed to form logic gates. Meanwhile, in the case that a dielectric layer is disposed in the select gate of the memory cell, preferably, in the upper strip of the select gates formed in the memory array region, at a location directly over each via hole below in the dielectric layer, etching is performed to form a via hole with a bottom side extended through and internally electrically connected to the below via hole in the dielectric layer, and a top side exposed out on upper surface of the upper strip of the select gates.

F. Forming source and drain

On two side surfaces of each gate formed above, a spacer is formed by an isolation dielectric material to play a role of electrical insulation. Meanwhile, if via holes are formed in the upper strip of the select gates, an isolation wall is also formed on the inner surface of the via holes, and also formed on the inner surface of via holes in below dielectric layer. If no via hole is formed in the upper strip of the select gates, no need to form an isolation wall on the inner surface of via holes in the dielectric layer.

Then, beside the spacer of each gate, dopant ions are implanted into active areas on the surface of substrate, to form diffusion regions of source and drain of the memory cell, which are located on sides of the select gate and the stacked gate respectively, and to form diffusion regions of source and drain of the logic transistor. In the memory cell, a dopant ion diffusion region formed in the substrate between two stacked gates is a common source; and a dopant ion diffusion region formed in the substrate on the side of the select gate opposite to the stacked gate is a drain of the select gate.

Subsequently, the gate oxide layer remained on the surface of the active areas over each source or drain is stripped away by acid. A common line (COM) is formed by self-aligned polysilicide over the common source between two stacked gates in the memory cell, coupled to the below common source in the substrate. The drain in the substrate on the side of the select gate opposite to the stacked gate in the memory cell is coupled to a bit Line (BL). If no dielectric layer present in the select gate in the memory cell, the upper part and the lower part of the select gate merge together and coupled to a word Line (WL).

In the case that a dielectric layer is present in the select gate, if the via hole is absent in the upper strip of the select gates, the lower strip of the select gates is electrically connected to the upper strip of the select gate through the via hole in the dielectric layer and is coupled to the word Line (WL). If the via hole is present in the upper strip of the select gate, with a bottom side extended through to below via hole in the dielectric layer, and an isolation wall formed on inner surface of the via hole and also on inner surface of below via hole in dielectric layer, a wire is formed inside at the center of the vertically through via holes by etching with a photomask and filling with metal tungsten. The bottom of the wire is electrically connected to upper surface of lower strip of the select gates, and the top of the wire is exposed out of upper surface of upper strip of the select gates, and is coupled to the word Line (WL), so that the lower strip of the select gates is connected to the word Line (WL), whereas the upper strip of the select gates is not connected to the word Line (WL). When the etching is performed inside the via holes, a photomask is adopted, and the isolation wall on the inner surface of the via holes is not etched off.

All elements of the memory cell and the logic transistor are made of conventional materials in the industry. The common line is preferably made of self-aligned polysilicide, and the gate is preferably made of polysilicon. The dielectric layer and the spacer are made of conventional materials well known in the industry.

The embedded flash memory of 110 nm or less of the present invention is described in detail below with reference to the accompanying drawings, but the scope of the present invention is not limited to the specific embodiments shown in the accompanying drawings.

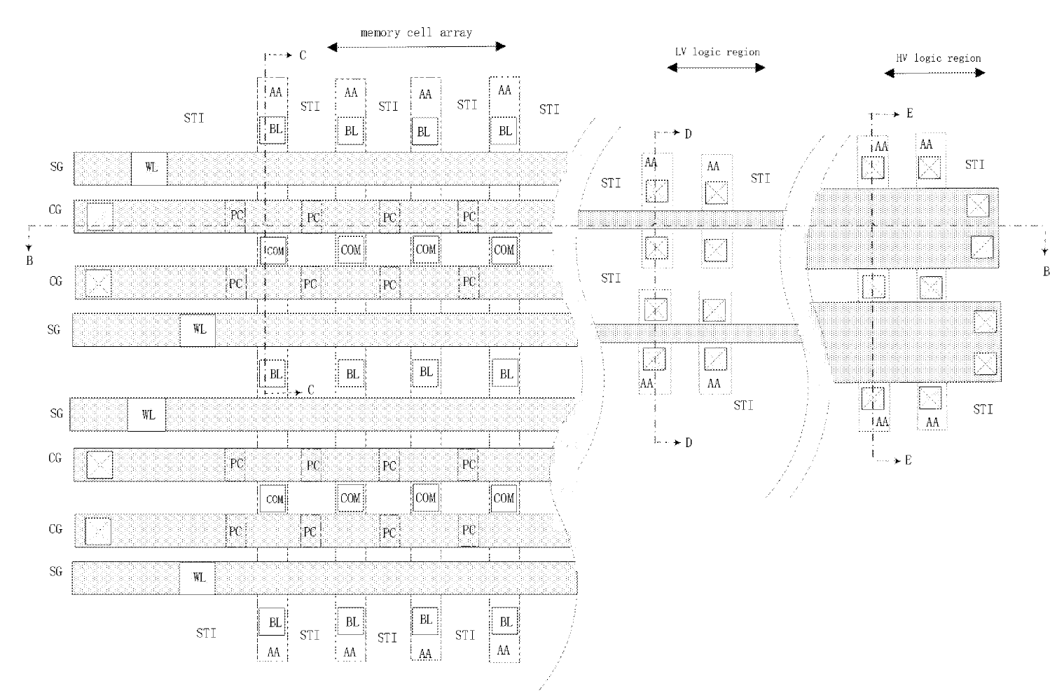

FIG. 1 is a partial top view of a specific embodiment of a 90 nm embedded flash memory of present invention. In FIG. 1, only a part of a memory array composed of 8 memory cells in the flash memory and a part of peripheral low-voltage logic region and high-voltage logic region are shown. In the low-voltage logic region, 4 mutually independent low-voltage standard logic transistors are shown; and in the high-voltage logic region, 4 high-voltage standard logic transistors are shows, with two connected in series. In the flash memory, the memory cell array and the peripheral logic region (including low-voltage region and high-voltage region) reside in one substrate.

All memory cells in the flash memory shown in FIG. 1 are identical, locate in and share a N-well (not shown in FIG. 1) fabricated in the substrate. All elements of the memory cell are PMOS type. The four low-voltage standard logic transistors in the low-voltage logic region shown in FIG. 1 are identical, of NMOS type, locate in and share a P-well. The four high-voltage standard logic transistors in the high-voltage logic region are identical, of PMOS type, locate in and share a N-well. P-well and N-well of logic transistors in the logic region are also fabricated in the substrate (not shown in FIG. 1). All logic transistors (or logic elements) in the logic region (including low-voltage and high-voltage logic regions) have a gate with the same height. These gates are formed by depositing a layer of the same gate material simultaneously in the same deposition step and followed by etching.

In FIG. 1, both of the memory cells and the peripheral logic transistors are fabricated in active areas (AA) on the surface of the substrate. On the surface of the substrate, active areas and shallow trench isolation (STI) areas are alternately arranged in parallel and adjacent to each other.

In the memory array shown in FIG. 1, all memory cells are oriented identically. A straight line connecting the same point of two select gates in a memory cell extends in a column direction in the array, and adjacent odd column and even column are separated by a shallow trench Isolation (STI). The array shown in the figure includes 4 memory cells in each row and 2 memory cells in each column.

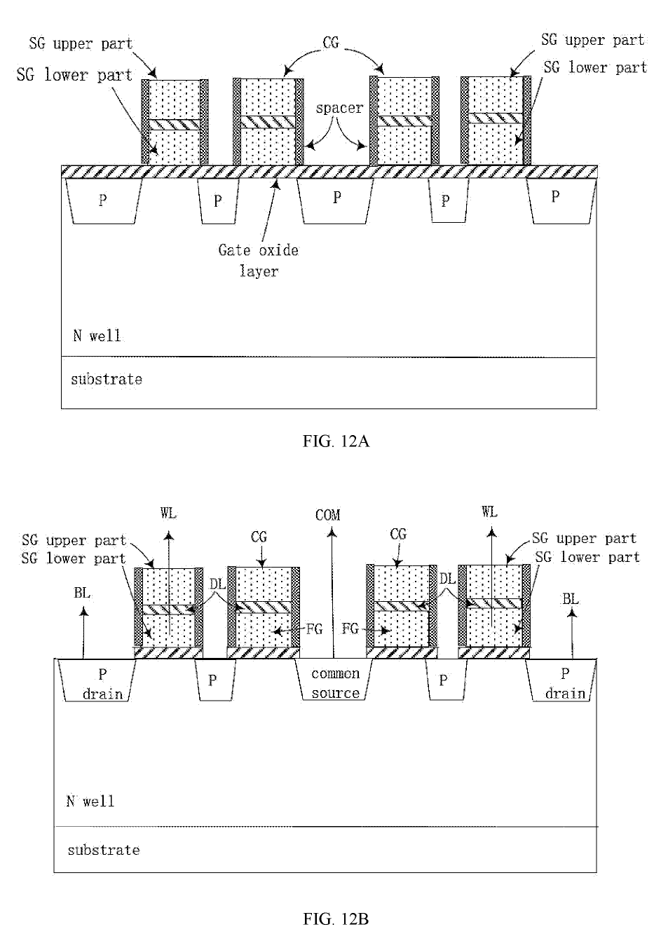

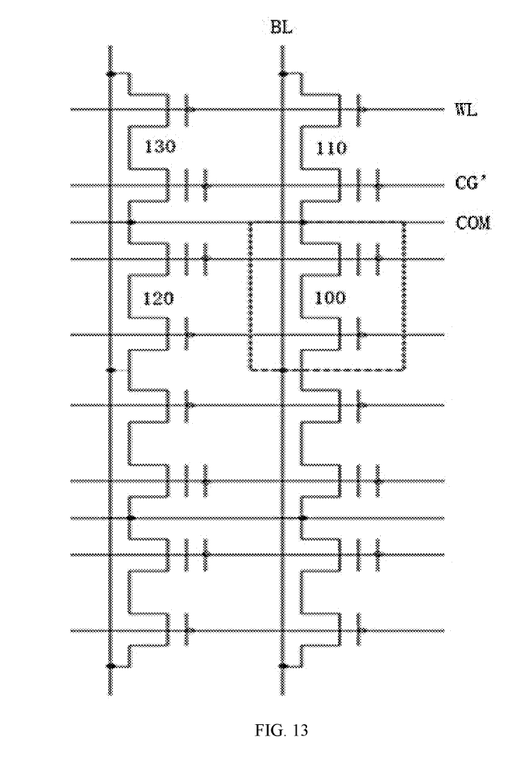

The structure of the memory cell is shown in FIG. 12B, which is a structure of a memory cell in the flash memory shown in FIG. 1 taken along the section line C-C. The memory cell includes: a common source of P type in the substrate; a common line (COM) located directly over the common source with a bottom connected to the common source; a pair of stacked gates on the substrate, located respectively on two sides of the common line in bilateral mirror symmetry, each of the stacked gates includes a Control Gate (CG) and a Floating Gate (FG) vertically stacked and self-aligned with each other, and a dielectric layer (DL) therebetween; a pair of Select Gates (SG) on the substrate, located respectively on the side of the stacked gate opposite to the common line in bilateral mirror symmetry along the common line, and aligned with the stacked gates along the column. A drain is located in the substrate on one side of the select gate opposite to the stacked gate. Each of the select gate includes an upper part, a lower part, and a dielectric layer (DL) therebetween. The common source of the memory cell is coupled electrically to the common line (COM), the control gate is coupled electrically to a control line (CG') (not shown in FIG. 12B), the drain of the select gate is coupled to a Bit Line (BL); and the lower part of the select gate is coupled to a Word Line (WL).

The control gate in the memory cell has the same height as the logic gate in the logic transistor, and the both gates are formed by depositing a layer of the same gate material simultaneously in the same deposition step, and followed by separately etching.

In the memory cell, the select gate is completely identical to the stacked gate in structure and height. The upper gate part, the lower gate part, and the intermediate dielectric layer of the select gate, are identical respectively to the control gate, the floating gate, and the intermediate dielectric layer of the stacked gate in height, structure, and components. The select gate and the stacked gate are formed through the same manufacturing steps. Specifically, all corresponding parts of the select gate and the stacked gate are made of the same material through the same manufacturing steps. The upper part, the lower part and the intermediate dielectric layer of the select gate correspond respectively to the control gate, the floating gate and the intermediate dielectric layer of the stacked gate.

All components of the memory cell and the logic transistor are made of conventional materials in the industry. For example, the common line is made of self-aligned polysilicide, and the gate is made of polysilicon.

In the memory array as shown in the figure, in each row, the corresponding upper parts of select gates, the corresponding lower parts of select gates, and the corresponding control gates of all memory cells, are respectively connected into a strip along the row, across and over isolation areas (STI) between adjacent columns, and the strips are parallel to each other. However, the corresponding floating gates of the memory cells in each row, are not connected, and interrupted by the gap (PC) between two corresponding floating gates of adjacent memory cells in each row as shown in FIG. 1, which is formed by etching.

Via holes are formed in the dielectric layer between the vertically aligned upper gate strip and lower gate strip of the select gates in each row. A via hole is formed in the dielectric layer between the upper and lower strips of the select gates at an interval of every 16 memory cells along the row, with a bottom side contacted with and electrically connected to upper surface of the lower strip of the select gates, and a top side exposed out on upper surface of the dielectric layer. In the upper strip of the select gates in the row, a via hole is also formed at a location directly over each below via hole in the dielectric layer, isolating to the surrounding upper strip of the select gates, with a top side exposed out of upper surface of the upper strip of the select gates, and a bottom side extended through and electrically connected to the below via hole in the dielectric layer. An isolation wall is present on the inner surface of the upper and lower via holes, and a metal wire stands upright inside at the center of the via holes. The wire has a bottom side electrically connected to the upper surface of the lower strip of the select gates, and a top side coupled to a Word Line (WL), so that the lower strip of the select gates in each row can be electrically extended out and coupled to above Word Line (WL), but the upper strip of the select gates is not coupled to the Word Line (WL).

In each column, Bit lines (BL) of the memory cells are connected, and in each row, word lines (WL), common lines (COM), and control lines (CG') of the memory cells are respectively connected. As shown in FIG. 13.

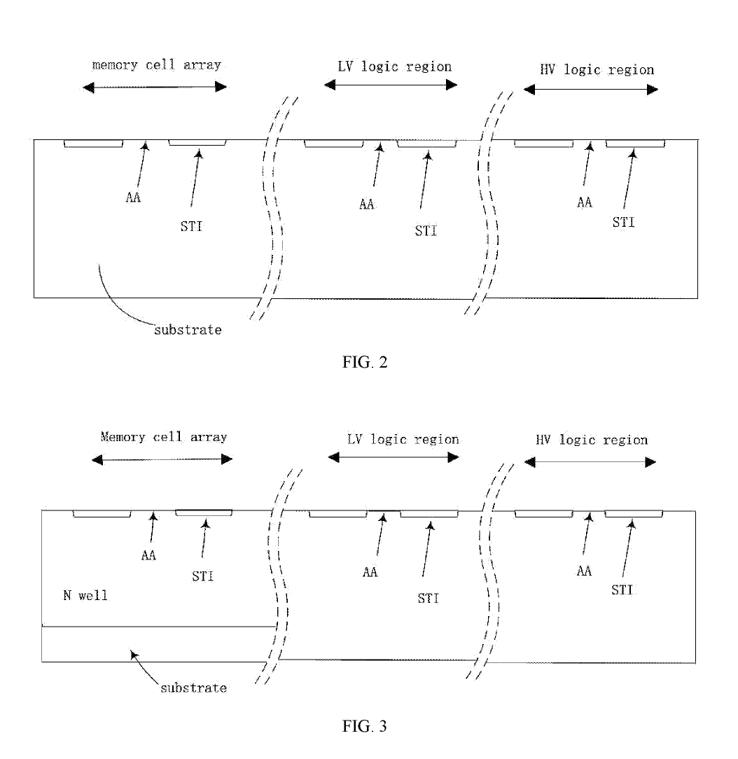

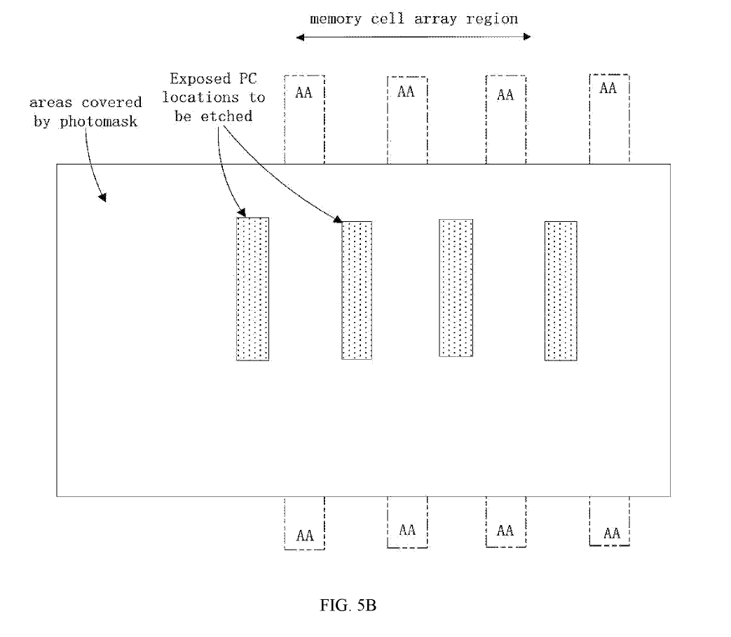

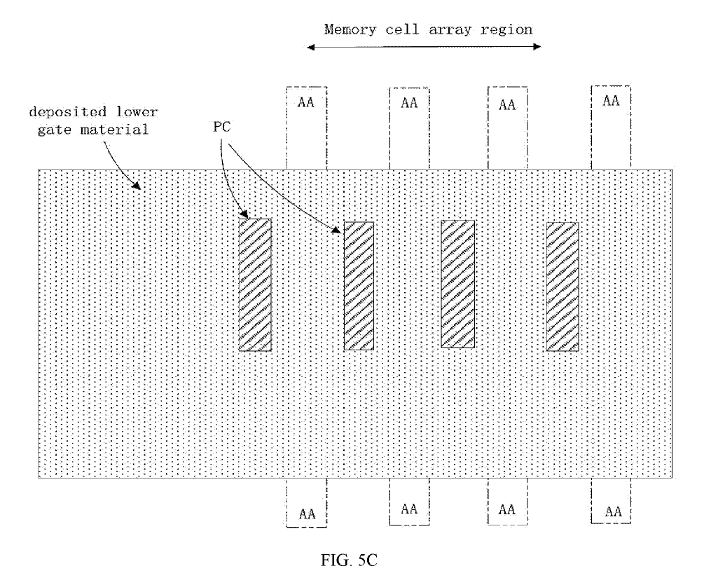

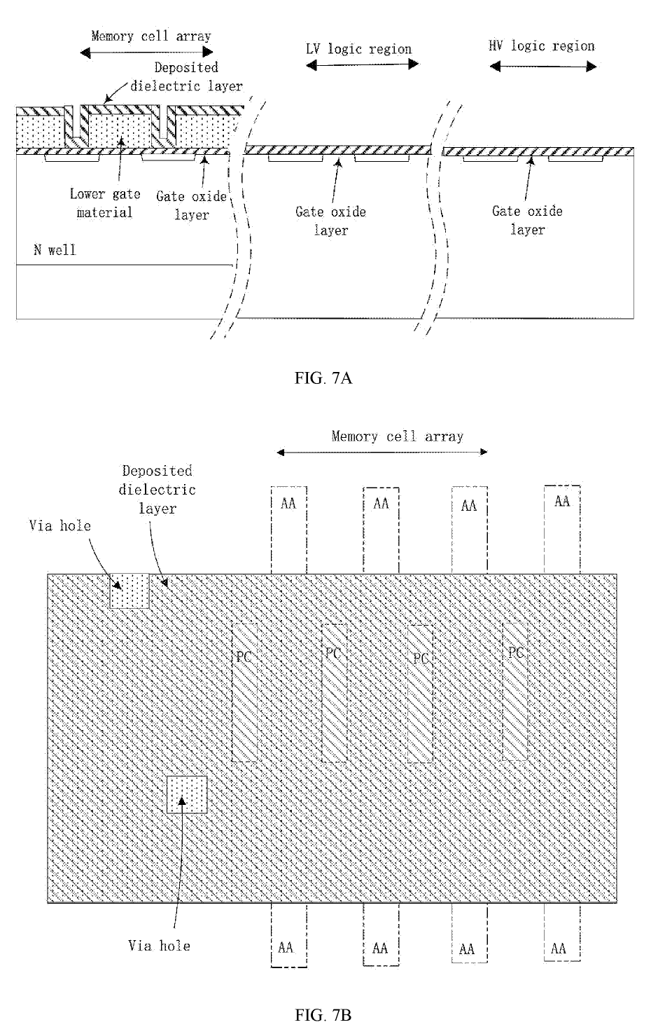

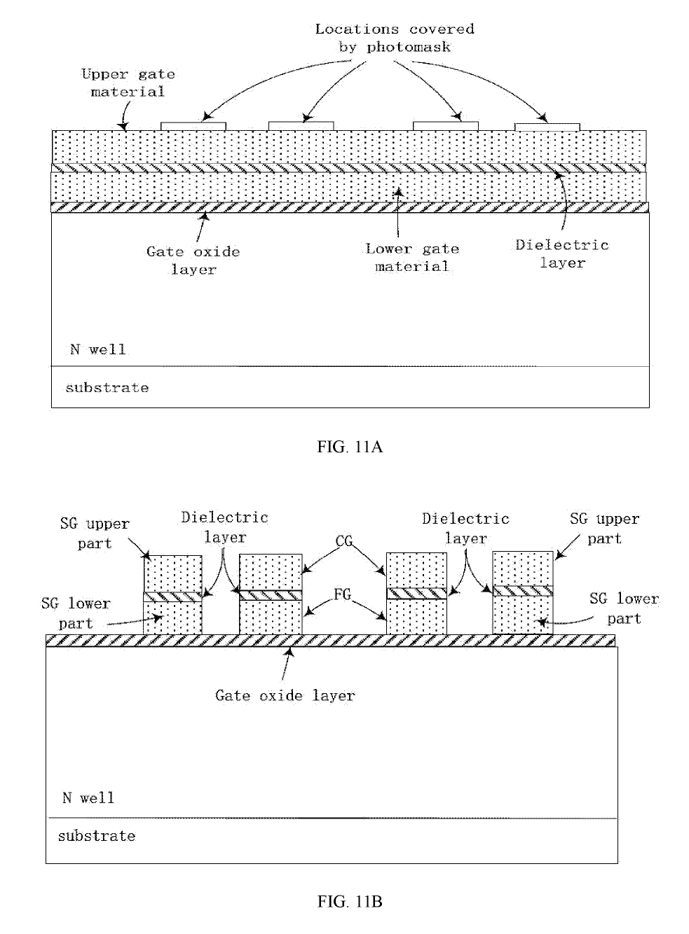

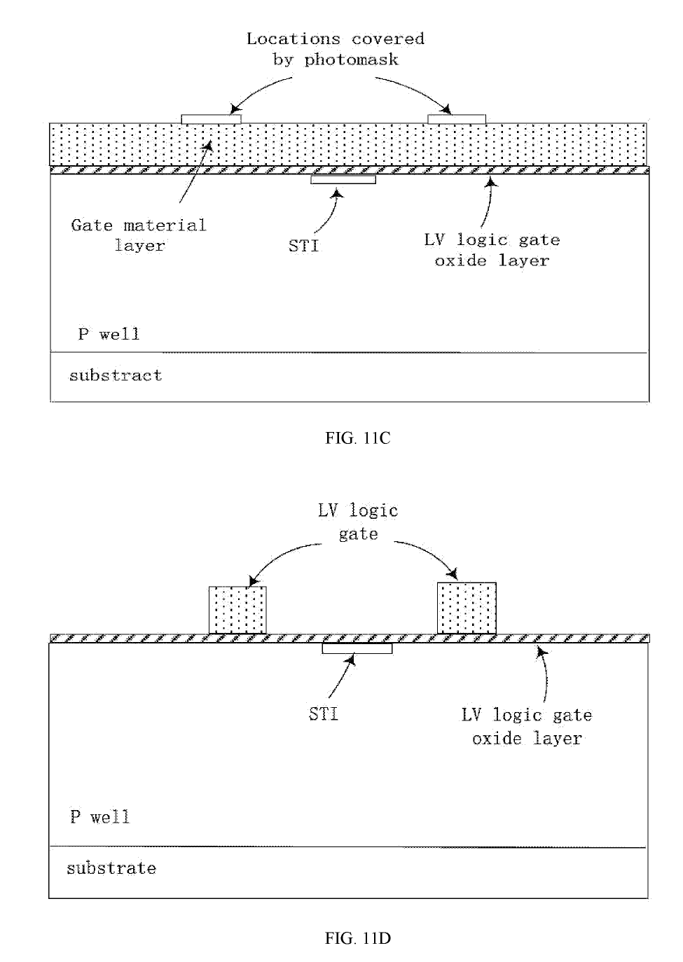

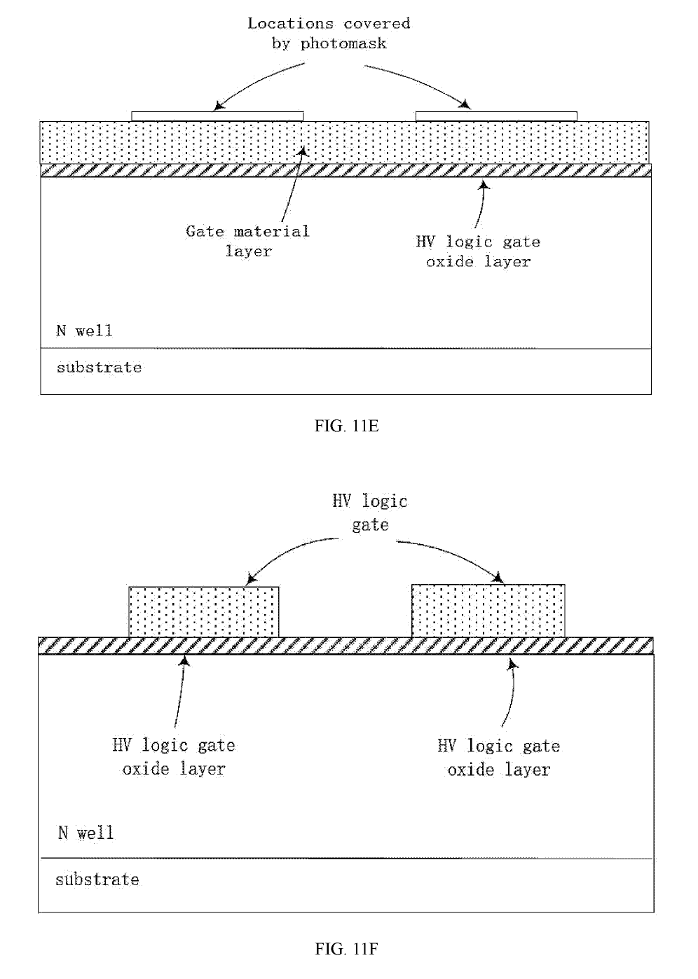

FIGS. 2-10 (except FIGS. 5B-5C and 7B) are schematic diagrams of the structure of a part of memory cells and logic transistors in the flash memory of FIG. 1 taken along the section line B-B in the manufacturing process (in steps before etching to form gates) respectively. FIGS. 11A-12B show respectively the steps of forming gates, sources, and drains of memory cells and logic transistors respectively. The manufacturing process of the flash memory shown in FIG. 1 is described in detail below with reference to these drawings.

A. Providing a substrate and forming a well of the memory cell:

FIG. 2 is a schematic diagram of the substrate in the flash memory of FIG. 1 taken along the section line B-B before the elements start to be formed. Active areas (AA) and shallow trench isolation (STI) areas are alternately present and adjacent to each other on the surface of the substrate. Memory cells and logic transistors are later formed in the active areas. As shown in FIG. 3, firstly, a N-well of the memory cells in the memory array is formed in the substrate, under a predefined area of the memory array region on the surface of the substrate.

B. Depositing layers of gate oxide and lower gate material and followed by etching:

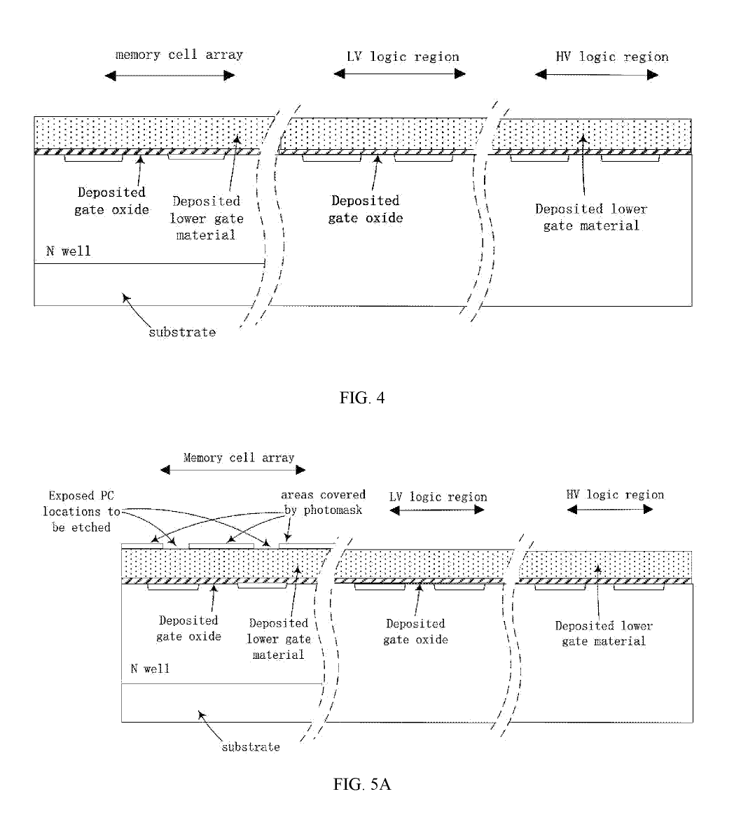

As shown in FIG. 4, a layer of gate oxide material is simultaneously deposited in predetermined areas of the memory array region and peripheral logic region on the surface of the substrate. Then, a layer of lower gate material is deposited on entire surface of the gate oxide layer. The thickness of the gate oxide layer is about 85 Å, and the thickness of the lower gate layer (i.e. the thickness of the floating gate formed later) is about 800 Å.

Then, in the predefined area of each row of memory cells, at the predetermined location of the gap between two adjacent memory cells, particularly at the predetermined location of the gap (PC) between two corresponding floating gates of two adjacent memory cells in the row, the layer of lower gate material is etched away by a photomask, to form the gap (PC) between two corresponding floating gates of adjacent memory cells. In the predefined area of the logic region (including low-voltage logic region and high-voltage logic region), the layer of deposited lower gate material is also etched away.

FIGS. 5A and 5D are respectively a diagram of the structure of a part of memory cells and logic transistors in the flash of FIG. 1 taken along section line B-B, in the steps before and after etching in the layer of deposited lower gate material in the predefined area in memory array region to form the gap (PC) between two corresponding floating gates of adjacent memory cells in each row of memory cells. In FIG. 5A, the structure taken along the section line B-B before etching is shown, with a photomask placed on the deposited lower gate layer, wherein the predetermined locations of the gaps (PC) to be etched are exposed.

FIGS. 5B-5C are respectively a top view of a row of memory cells in the flash of FIG. 1 in the steps before and after etching to form the gap (PC) between two corresponding floating gates of adjacent memory cells in the row, in which only the predefined area of 4 memory cells in the row are shown. In FIG. 5B, it is shown that before etching, a photomask (also referred to as a photolithography mask) is placed on the deposited lower gate layer in the memory array region, shielding most surface of the lower gate layer, and only the predefined locations of the gaps (PC) to be etched are exposed. Then, the etching is performed to remove the exposed lower gate material, so as to form the gap (PC) between the corresponding floating gates of adjacent memory cells in the row, as shown in FIG. 5C. In a row, each memory cell has two floating gates disconnected respectively from the corresponding floating gates of an adjacent memory cell by the gaps formed thereby.

C. Depositing a layer of dielectric oxide and followed by etching:

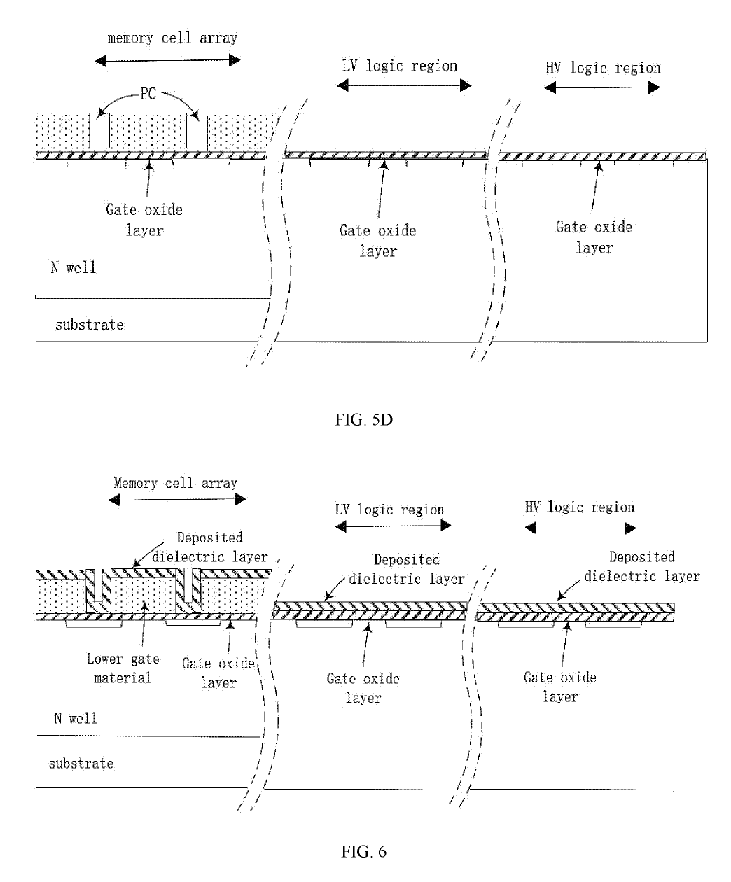

As shown in FIG. 6, a layer of dielectric oxide material, i.e., a dielectric layer, is simultaneously deposited on the lower gate layer in the memory array region and on the gate oxide layer in the logic region.

Then, as shown in FIG. 7A, the dielectric layer deposited in the logic region is etched and removed by using a photomask. Meanwhile, in the memory array region, in the predefined area of each row of memory cells, a via hole is formed by etching in a part of dielectric layer directly over the predefined location of lower part of the select gates at an interval of every 16 memory cells along the row. The bottom side of the via hole contacts with upper surface of lower gate layer, and the top side of the via hole is exposed out of top surface of the dielectric layer. The via hole is not shown in FIG. 7A, but shown in FIG. 7B. FIG. 7B is a top view of a row of memory cells in the flash of FIG. 1 in the step after forming via holes by etching in the dielectric layer, in which only a predetermined area of 4 memory cells in the row are shown, and two via holes are formed respectively in the part of dielectric layer directly over the predefined area of lower part gate layer of two selected gates.

D. Forming wells for logic transistors in logic region and a layer of logic gate oxide

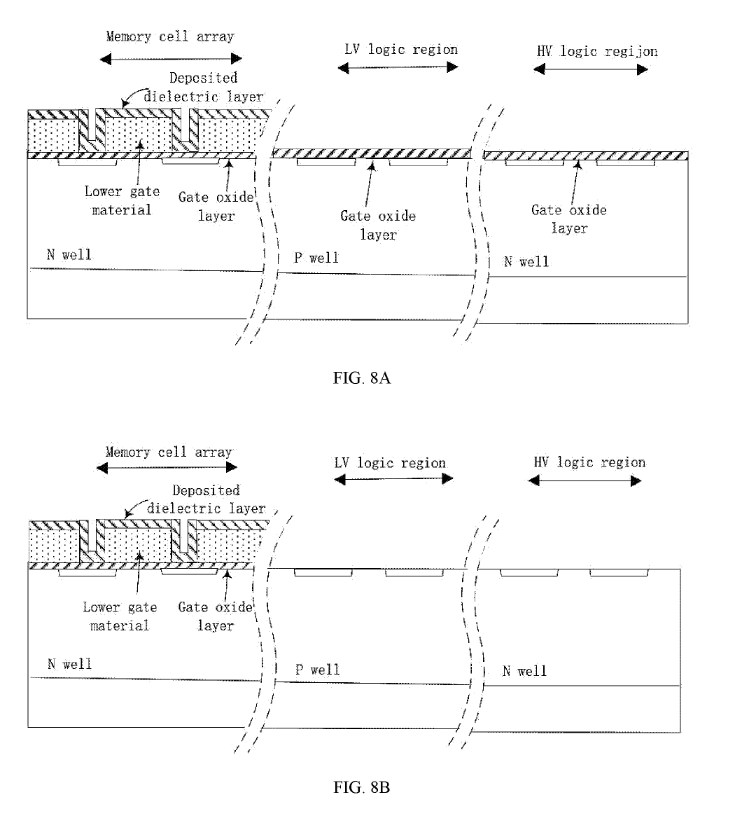

As shown in FIG. 8A, wells for logic transistors are formed in the substrate below the predefined area of the logic region. The low-voltage (LV) standard logic transistors in the low-voltage (LV) logic region are NMOS transistors located in a P-well. The high-voltage (HV) standard logic transistors in the high-voltage (HV) logic region are PMOS transistors, located in a N-well.

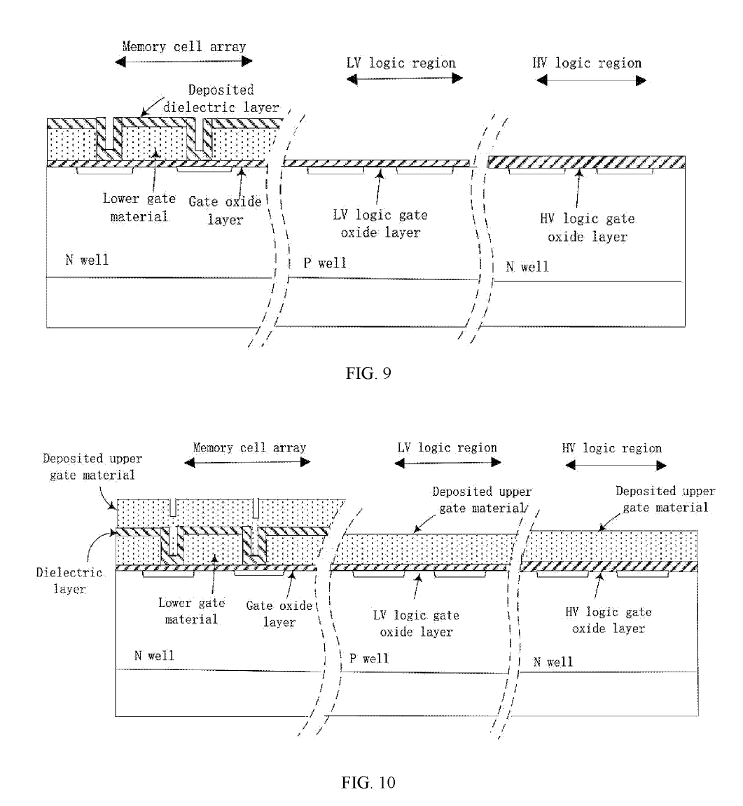

Then, as shown in FIG. 8B, the residual layer of gate oxide previously formed in the logic region along with the fabrication of memory cells, is removed by etching; and a new layer of logic gate oxide specifically for the logic gate is regrown in the logic region, as shown in FIG. 9. A certain gap exists between the regrown layer of logic gate oxide in the logic region and the layer of gate oxide in the memory array region. The logic gate oxide layer in the low-voltage logic region is different from that in the high-voltage logic regions in thickness. The logic gate oxide layer in the low-voltage logic region is relatively thin, about 25 Å, while that in the high-voltage logic region is thicker, approximately 65 Å. Thus, the operating voltage of low-voltage logic transistors is about 1.1 V, and that of high-voltage logic transistors is about 2.5 V. In addition, a thicker logic gate oxide layer of about 120 Å can be formed in the high-voltage logic region to obtain 5 V high-voltage logic elements.

E. Depositing a layer of upper gate material and forming gates by etching

As shown in FIG. 10, a layer of upper gate material is simultaneously deposited on the dielectric layer in the memory array region and on the logic gate oxide layer in the logic region.

Then, in the memory array region, in the predefined area of each row of memory cells, a photomask is used to cover the predefined locations of select gates and control gates, and in the area outside these locations, etching is performed down, till stopped at upper surface of the gate oxide layer, to remove together the upper gate layer, lower gate layer and the intermediate dielectric layer in the area, thereby forming the floating gates, strips of the upper parts of the select gates, strips of the lower parts of the select gates, strips of the control gates in each row simultaneously. In each row, two strips of upper gate parts of the select gates, two strips of lower gate parts of the select gates, and two strips of control gates, are present in parallel along the row direction, as shown in the memory array in FIG. 1.

FIGS. 11A-11B are schematic diagrams of the structure of a memory cell in the flash memory of FIG. 1 taken along the cross-section line C-C in the column direction, respectively in the steps before and after etching to form gates. In FIG. 11A, the locations of the memory cell covered by the photomask are shown, i.e., the predetermined locations for the select gates and control gates to be formed. In FIG. 11B, the upper and lower parts of the select gates (SG), and the floating gates (FG) and the control gates (CG) of the stacked gates in the memory cell formed after etching, are shown.

Subsequently, in the logic region, a photomask is used to cover the predefined locations of logic gates, then in the area outside these locations, the layer of upper gate material is etched away to form logic gates. In FIGS. 11C-11D, the structure of the low-voltage logic elements in the flash memory of FIG. 1 taken along the cross-section line D-D in the steps respectively before and after etching to form the low-voltage logic gates, are shown. In FIGS. 11E-11F, the structure of the high-voltage logic elements in the flash memory of FIG. 1 taken along the cross-section line E-E in the steps respectively before and after etching to form the high-voltage logic gates, are shown. The photomask-covered locations in FIGS. 11C and 11E, are respectively the predefined locations of the low-voltage logic gates and high-voltage logic gates to be formed.

At the same time, in each row in the memory array region, a via hole is formed by etching in the strip of upper parts of select gates, at a location directly over each via hole in the below dielectric layer, with a bottom side extended through and internally electrically connected to the below via hole in the dielectric layer, so as to extend the below via hole upward and out, and with a top side exposed out on upper surface of the upper strip of the select gates.

F. Forming source and drain

A spacer is formed of an insulating dielectric material on both sides of each gate formed by etching, for electrical insulation. Meanwhile, an isolation wall is also formed on the inner surface of the via holes formed in the upper strip of select gates and in the dielectric layer.

Then, on outer side of the spacer of each gate, dopant ions are implanted into active areas on the surface of substrate, to form P type diffusion regions of source and drain in the memory cell, located beside the select gate and the stacked gate respectively (as shown in FIG. 12A). Similarly, P or N type diffusion regions of source and drain of the logic transistor in peripheral logic region are formed.

In the memory cell, a dopant ion diffusion region formed in the substrate between two stacked gates is a common source; and a dopant ion diffusion region formed in the substrate on the side of the select gate opposite to the stacked gate is a drain of the select gate.

Subsequently, the gate oxide layer remained directly over each source or each drain in the active areas on the surface of the substrate is stripped away by acid. A self-aligned polysilicide is formed over the common source and between two stacked gates in the memory cell, which is a common line (COM), coupled to the below common source in the substrate. The drain in the substrate on the side of the select gate opposite to the stacked gate in the memory cell is coupled to a bit Line (BL).

A conductive wire is formed inside at the center of the vertically-through via holes present in upper gate strip of selective gates and in the dielectric layer, by etching with a photomask and filling with metal tungsten. The wire has a bottom side electrically connected to upper surface of the lower gate strip of the select gates, and a top side exposed out of upper surface of upper gate strip of the select gates and coupled to the word Line (WL), so that the lower gate strip of the select gates is connected to the word Line (WL), whereas the upper gate strip of the select gates is not connected to the word Line (WL). As the etching is performed inside the via hole, a photomask is adopted, and the isolation wall on the inner surface of the via hole is not etched off.

Operation of above Embedded Flash Memory of 90 nm

FIG. 13 is a circuit schematic diagram of a 2×2 memory array of the flash memory shown in FIG. 1. During operation, half a memory cell serves as a unit for operation of programming, read, or erase. In the circuit diagram of the memory array shown in FIG. 13, the upper row includes 2 memory cells, one of which includes the first half-cell portion 100 and the second half-cell portion 110, the other includes the third half-cell portion 120 and the fourth half-cell portion 130. An embodiment of operations of the flash is exemplified by the four half-cell portions of the two memory cells, i.e. the first half-cell portion 100, the second half-cell portion 110, the third half-cell portion 120, and the fourth half-cell portion 130. The structure of each memory cell is shown in FIG. 12B.

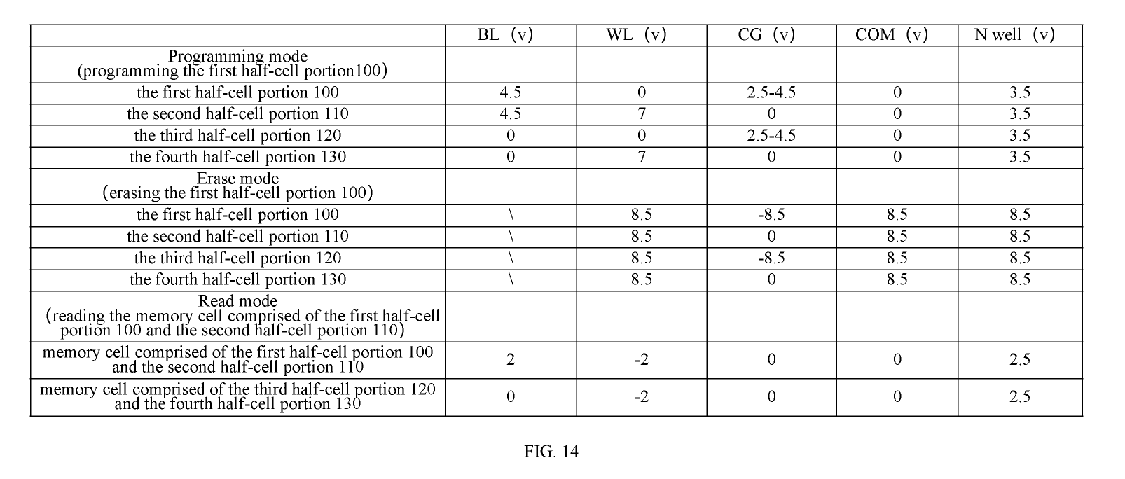

FIG. 14 shows the bias voltage signals connected to the above four half-cell portions of the two memory cells during different operations.

The first half-cell portion 100 may be designated for independently programming. During programming operation, electrons are injected from channel region in the substrate near the common source into the floating gate. The first half-cell portion 100 may be programmed by driving BL to 4.5V, WL to 0V, CG to 2.5-4.5V, COM to 0V, and N-well to 3.5V.

The first half-cell portion 100 receives a word line (WL) voltage lower than that of the bit line BL and the N-well, and the voltage of the floating gate (FG) coupled from the control gate (CG) is also lower than that of the N-well, thereby an inversion channel is formed between the bit line diffusion region (i.e drain region) and the common source region in the substrate. The potential difference between the drain region and the source region is 4.5 V, creating a strong lateral electric field from the drain to the common source. Thus, holes are accelerated across the channel, causing impact ionization to occur at the depletion region of the common source. Hot electrons generated by impact ionization are attracted by the positively-biased control gate and injected into the floating gate. Therefore, the number of electrons in the floating gate increases during programming.

The second half-cell portion 110 receives a word line (WL) voltage of 7V, higher than that of the bit line (BL) and the N-well, so the channel between the drain and common source is turned off. Although there is a potential difference between the drain region and the source region, hole movement and impact ionization cannot occur, nor programming.

The voltages of the bit line diffusion region and source region of the third half-cell portion 120 are 0V, and the same applies to the fourth half-cell portion 130. So, no lateral electric field is formed in half-cell portion 120 or 130, and no programming occurs.

During erase operation, in the half-cell portion to be designated for erase, under the high potential difference between the floating gate and the underlying substrate, electrons trapped in the floating gate of the designated half-cell portion tunnel to the channel region in the underlying substrate.

The first half-cell portion 100 has the same bias signals for erase as the third half-cell portion 120, in which the bit line (BL) is in a floating state, and the voltage of the word line (WL) is the same as that of N-well. The voltage of the control gate (CG) is much lower than that of N-well and the common source region connected to the common line, so does the voltage of the floating gate FG coupled from the control gate CG. Since the potential difference between the floating gate and the N-well exceeds 10 V, a high vertical electric field is formed, sufficient to cause electrons trapped in the floating gate to tunnel into the channel in the substrate. The tunneling mechanism is the direct tunneling and/or Fowler-Nordheim tunneling.

The second half-cell portion 110 has the same bias signals for erase as the fourth half-cell portion 130, in which the voltage of control gate CG is 0 V, and the coupled voltage of the floating gate FG is also 0V. Due to a small potential difference between the floating gate and the N-well, electron tunneling from the floating gate to the channel in the substrate cannot be trigged.

Alternatively, the erase bias signals of the four half-cell portions of the two memory cells can be set uniformly, so that the four half-cell portions can perform erase simultaneously.

During read operation, the data in a column of memory cells can be read out simultaneously. The bit lines BL of the first half-cell portion 100, the second half-cell portion 110, the third half-cell portion 120, and the fourth half-cell portion 130 may be selected, and the half-cell portion to be read is selected based on whether the word line WL turns on the portion.

The voltages of the word line (WL) of the first half-cell portion 100 and the second half-cell portion 110 are lower than that of the bit line (BL) and the N-well, and the voltage of the floating gate FG coupled from the control gate CG is 0 V, also lower than that of the bit line and the N-well, thereby an inversion channel is formed between the bit line diffusion region and the common source region in the substrate. Moreover, a 2 V potential difference exists between the bit line diffusion region and the common source region, creating a lateral electric field and thus generating a read current.

The voltages of the bit line diffusion regions and common source regions of the third half-cell portion 120 are 0V, so does the fourth half-cell portion 130, no lateral electric field is formed, so no read current is generated.

Although the present invention is described in detail only for the preferred embodiments herein, those of ordinary skill in the art will recognize that other changes and modifications can be made without departing from the scope of the present invention as defined by the claims.

1. An embedded flash memory of 110 nm or less, comprising a substrate, and a memory cell array region and a peripheral logic region on the substrate,
wherein the memory cell array region comprises at least one memory cell comprising:
a common source in the substrate;
a common line over the common source and connected thereto;
a pair of stacked gates located respectively on two sides of the common line, each stacked gate comprising a floating gate and a control gate vertically over the floating gate; and
a pair of select gates located respectively on the side of the stacked gate opposite to the common source line;
wherein the peripheral logic region comprises at least one standard logic transistor comprising a logic gate;
the control gate in the memory cell has the same height as the logic gate in the standard logic transistor; and
the control gate and the logic gate are formed by depositing a layer of gate material in the same deposition step, but followed by separate etching, in a fabrication process of standard logic transistors.

2. The embedded flash memory of 110 nm or less according to claim 1, wherein the select gate has the same or substantially the same height as the stacked gate, the select gate comprises an upper gate part and a lower gate part, and the stacked gate further comprises a dielectric layer sandwiched between the control gate and the floating gate;
wherein the select gate has substantially the same height as the stacked gate, means that no dielectric layer is present between the upper part and the lower part in the select gate, and a height of the select gate is slightly lower than that of the stacked gate by a height of the dielectric layer in the stacked gate.

3. The embedded flash memory of 110 nm or less according to claim 2, wherein the select gate and the stacked gate are identical in structure and height; the upper part and lower part in the select gate have an identical height respectively to the control gate and the floating gate, a dielectric layer is also present between the upper part and the lower part in the select gate and has the same height as the dielectric layer in the stacked gate; and the lower part of the select gate is electrically connected to above the dielectric layer.

4. The embedded flash memory of 110 nm or less according to claim 2, wherein:
the memory array is comprised of rows and columns, and all memory cells in the array are orientated identically;
in the case that the direction of a straight line connecting the same points of two select gates in a memory cell is column direction, the corresponding upper parts of the select gates or the corresponding control gates of the memory cells in each row are connected along the row to form a strip; whereas the corresponding floating gates of the memory cells in each row are not connected and interrupted at gaps between two adjacent memory cells; or
in the case that the direction of a straight line connecting the same points of two select gates in a memory cell is row direction, the corresponding upper parts of the select gates or the corresponding control gates of the memory cells in each column are connected along the column to form a strip; whereas the corresponding floating gates of the memory cells in each column are not connected and interrupted at gaps between two adjacent memory cells;
wherein the corresponding gates of the memory cells in each row mean the gates at the same position in the memory cells in the row, which can be connected into a straight line along the row, referring to select gates, upper parts of select gates, lower parts of select gates, control gates, or the floating gates; the same applies to the corresponding gates of the memory cells in each column.

5. The embedded flash memory of 110 nm or less according to claim 4, wherein:
in the memory cell, the select gate and the stacked gate are identical in structure and height; the upper part and the lower part in the select gate have an identical height respectively to the control gate and the floating gate, a dielectric layer is also present between the upper part and the lower part in the select gate and has the same height as the dielectric layer in the stacked gate;
in the memory array, in the case that the direction of a straight line connecting the same points of two select gates in a memory cell is column direction, the corresponding upper parts, corresponding lower parts, or corresponding intermediate dielectric layers of the select gates of the memory cells in each row, are connected along the row to form a strip; in each row, at least one via hole is formed in the dielectric layer between the vertically aligned upper strip and lower strip of the select gates, with a bottom side electrically connected to an upper surface of the lower strip of the select gates and a top side exposed out on an upper surface of the dielectric layer, so that the lower strip of the select gates is electrically connected to above the dielectric layer; or
in the memory array, in the case that the direction of a straight line connecting the same points of two select gates in a memory cell is row direction, the corresponding upper parts, corresponding lower parts, or corresponding intermediate dielectric layers of the select gates of the memory cells in each column, are connected along the column to form a strip; in each column, at least one via hole is formed in the dielectric layer between the vertically aligned upper strip and lower strip of the select gates, with a bottom side electrically connected to an upper surface of the lower strip of the select gates, and a top side exposed on an upper surface of the dielectric layer, so that the lower strip of the select gates is electrically connected to above the dielectric layer.

6. The embedded flash memory of 110 nm or less according to claim 5, wherein:
in the memory array, in the case that the direction of a straight line connecting the same points of two select gates in a memory cell is column direction, in each row, at least one via hole is also formed in the upper strip of select gates at a position vertically over the below via hole in the dielectric layer, which is electrically insulated from the surrounding upper strip of select gates and internally electrically connected to the below via hole in the dielectric layer, with a bottom side extended through to the below via hole in the dielectric layer, and a top side exposed on an upper surface of the upper strip of select gates; or
in the memory array, in the case that the direction of a straight line connecting the same points of two select gates in a memory cell is row direction, in each column, at least one via hole is also formed in the upper strip of select gates at a position vertically over the below via hole in the dielectric layer, which is electrically insulated from the surrounding upper strip of select gates and internally electrically connected to the below via hole in the dielectric layer, with a bottom side extended through to the below via hole in the dielectric layer, and a top side exposed on an upper surface of the upper strip of the select gate.

7. The embedded flash memory of 110 nm or less according to claim 5, wherein:
in the memory array, in the case that the direction of a straight line connecting the same points of two select gates in a memory cell is column direction, in each row, a via hole is formed in the dielectric layer between the vertically aligned upper strip and lower strip of select gates at an interval of from 16 to 32 memory cells along the row; or
in the memory array, in the case that the direction of a straight line connecting the same points of two select gates in a memory cell is row direction, in each column, a via hole is formed in the dielectric layer between the vertically aligned upper strip and lower strip of select gates at an interval of from 16 to 32 memory cells along the column.

8. The embedded flash memory of 110 nm or less according to claim 1, wherein it is an embedded flash memory device of 90 nm or less.

9. A method for manufacturing the embedded flash memory of 110 nm or less according to claim 1, comprising the following steps:
forming the control gate in the memory cell and the logic gate in the standard logic transistor by depositing simultaneously a layer of gate material on predefined areas of the memory array region and the peripheral logic region in the same deposition step, and then separately etching the layer of gate materials in the memory array region and the peripheral logic region by using different photomasks.

10. The method for manufacturing the embedded flash memory of 110 nm or less according to claim 9, further comprising the following step:
before forming the control gate and the logic gate, in the peripheral logic region, etching to remove the deposited materials away from the surface of the substrate formed along with fabrication of memory cells in the memory array.

11. The method for manufacturing the embedded flash memory of 110 nm or less according to claim 9, wherein the select gate comprises an upper gate part and a lower gate part, and the stacked gate comprises a dielectric layer sandwiched between the control gate and the floating gate; the method further comprises the following steps:
in the case that the select gate has the same height as the stacked gate, the select gate comprises a dielectric layer sandwiched between the upper part and the lower part as well, and the select gate and the stacked gate are formed together through the same fabrication steps; or
in the case that no dielectric layer is present between the upper gate part and the lower gate part in the select gate, the select gate has substantially the same height as the stacked gate, namely, a height of the select gate is slightly lower than that of the stacked gate by a height of the dielectric layer in the stacked gate; in this case, the select gate and the stacked gate are formed together through substantially same fabrication steps, namely, the fabrication of the select gate only lacks of a step of depositing and forming a dielectric layer, as compared with the fabrication of the stacked gate.

12. The method for manufacturing the embedded flash memory of 110 nm or less according to claim 11, wherein:
the select gate and the stacked gate in the memory cell are identical in structure and height, the upper part and the lower part of the select gate have an identical height respectively to the control gate and the floating gate, a dielectric layer is sandwiched between the upper part and the lower part in the select gate with the same height as that in the stacked gate, and the lower part of the select gate is electrically connected to above the dielectric layer;
the memory array comprises rows and columns, and all memory cells in the array are orientated identically;
the method comprises the following steps sequentially:
1. depositing sequentially a layer of gate oxide material and a layer of lower gate material on the substrate; and etching by using a photomask to remove the layer of lower gate material at predefined locations of gaps between two adjacent memory cells, particularly at predefined locations of gaps between two corresponding floating gates of adjacent memory cells in predefined memory array region, and etching to remove the layer of lower gate material in predefined peripheral logic region, while retaining the layer of lower gate material unchanged in predefined areas of lower parts of select gates of memory cells in memory array region;
in the case that the direction of a straight line connecting same points of two select gates in a memory cell is column direction in the memory array, said step of etching to remove the layer of lower gate material in the memory array region is carried out in the predefined area of each row of memory cells along the row;
in the case that the direction of a straight line connecting same points of two select gates in a memory cell is row direction in the memory array, said step of etching to remove the layer of lower gate material in the memory array region is carried out in the predefined area of each column of memory cells along the column;
2. depositing a layer of dielectric material simultaneously on the layer of lower gate material in the memory array region and on the layer of gate oxide in the peripheral logic region; then etching by using a photomask to form at least one via hole in the layer of dielectric material in the memory array region, and etching to remove the layer of dielectric material in the peripheral logic region;
in the case that the direction of a straight line connecting same points of two select gates in a memory cell is column direction in the memory array, said step of etching to form the via hole in the layer of dielectric material comprises: in predefined area of each row of memory cells, in a part of the dielectric material layer directly over predefined area of lower parts of select gates, etching to form at least one via hole with a bottom side contacting an upper surface of the layer of lower gate material and a top side exposing out on an upper surface of the layer of dielectric material;
in the case that the direction of a straight line connecting same points of two select gates in a memory cell is row direction in the memory array, said step of etching to form the via hole in the layer of dielectric material comprises: in predefined area of each column of memory cells, in a part of the dielectric material layer directly over predefined area of lower parts of select gates, etching to form at least one via hole with a bottom side contacting an upper surface of the layer of lower gate material and a top side exposing out on an upper surface of the layer of dielectric material; and
3. depositing a layer of upper gate material simultaneously on the layer of dielectric material in the memory array region and on the layer of gate oxide in the peripheral logic region; and etching down by using a photomask to remove the layers of upper gate material, dielectric material, and lower gate material in areas outside predefined locations of select gates and control gates in the memory array region, till exposing an upper surface of the layer of gate oxide material, so as to form the floating gates of memory cells, and the strips of upper parts of select gates, the strips of lower parts of select gates, and the strips of control gates in the memory array region; and then etching by a photomask to remove the layer of upper gate material in areas outside predefined locations of logic gates, so as to form logic gates in the peripheral logic region.

13. The method for manufacturing the embedded flash memory of 110 nm or less according to claim 12, wherein:
said step of etching to form the via hole in the layer of dielectric material in the memory array, comprises:
in predefined area of each row of memory cells, in a part of the dielectric material layer directly over predefined area of lower parts of select gates, etching to form a via hole at an interval of from 16 to 32 memory cells along the row, in the case that the direction of a straight line connecting same points of two select gates in a memory cell is column direction; or
in predefined area of each column of memory cells, in a part of the dielectric material layer directly over predefined area of lower parts of select gates, etching to form a via hole at an interval of from 16 to 32 memory cells along the column, in the case that the direction of a straight line connecting same points of two select gates in a memory cell is row direction.

14. The method for manufacturing the embedded flash memory of 110 nm or less according to claim 12, wherein:
the step of etching to form the floating gates and the strips of upper parts of select gates, the strips of lower parts of select gates, and the strips of control gates in the memory array region, specifically comprises:
in predefined area of each row of memory cells, along the row, etching to form the floating gates, and two strips of upper parts of select gates, two strips of lower parts of select gates, and two strips of control gates in the row, in the case that the direction of a straight line connecting same points of two select gates in a memory cell is column direction; or
in predefined area of each column of memory cells, along the column, etching to form the floating gates, and two strips of upper parts of select gates, two strips of lower parts of select gates, and two strips of control gates in the column, in the case that the direction of a straight line connecting same points of two select gates in a memory cell is row direction.

15. The method for manufacturing the embedded flash memory of 110 nm or less according to claim 12, further comprising the following steps:
forming a well for the memory cell in the memory array in the substrate, before step (1);
forming a well for the standard logic transistor in the peripheral logic region in the substrate, after step (2) and before step (3), and
clearing the gate oxide layer away from the surface of the substrate in the peripheral logic region formed by deposition in step (1), and regrowing a layer of logic gate oxide in the logic region.

16. The method for manufacturing the embedded flash memory of 110 nm or less according to claim 9, wherein in the embedded flash memory of 110 nm or less, the select gate has the same or substantially the same height as the stacked gate, the select gate comprises an upper gate part and a lower gate part, and the stacked gate further comprises a dielectric layer sandwiched between the control gate and the floating gate;
wherein the select gate has substantially the same height as the stacked gate, means that no dielectric layer is present between the upper part and the lower part in the select gate, and a height of the select gate is slightly lower than that of the stacked gate by a height of the dielectric layer in the stacked gate.

17. The method for manufacturing the embedded flash memory of 110 nm or less according to claim 10, wherein the select gate comprises an upper gate part and a lower gate part, and the stacked gate comprises a dielectric layer sandwiched between the control gate and the floating gate; the method further comprises the following steps:
in the case that the select gate has the same height as the stacked gate, the select gate comprises a dielectric layer sandwiched between the upper part and the lower part as well, and the select gate and the stacked gate are formed together through the same fabrication steps; or
in the case that no dielectric layer is present between the upper gate part and the lower gate part in the select gate, the select gate has substantially the same height as the stacked gate, namely, a height of the select gate is slightly lower than that of the stacked gate by a height of the dielectric layer in the stacked gate; in this case, the select gate and the stacked gate are formed together through substantially same fabrication steps, namely, the fabrication of the select gate only lacks of a step of depositing and forming a dielectric layer, as compared with the fabrication of the stacked gate.

18. The method for manufacturing the embedded flash memory of 110 nm or less according to claim 13, further comprising the following steps:
forming a well for the memory cell in the memory array in the substrate, before step (1);
forming a well for the standard logic transistor in the peripheral logic region in the substrate, after step (2) and before step (3), and
clearing the gate oxide layer away from the surface of the substrate in the peripheral logic region formed by deposition in step (1), and regrowing a layer of logic gate oxide in the logic region.

19. The method for manufacturing the embedded flash memory of 110 nm or less according to claim 14, further comprising the following steps:
forming a well for the memory cell in the memory array in the substrate, before step (1);
forming a well for the standard logic transistor in the peripheral logic region in the substrate, after step (2) and before step (3), and
clearing the gate oxide layer away from the surface of the substrate in the peripheral logic region formed by deposition in step (1), and regrowing a layer of logic gate oxide in the logic region.
